(19) United States
(12) Patent Application Publication
(10) Pub. No.: US 2026/0282171 A1
(43) Pub. Date: Sep. 17, 2026

(54) INTEGRAL RESISTANCE HEATERS INCLUDING NIOBIUM AND PROCESSES FOR MAKING SAME

(71) Applicant: MATERION CORPORATION, Mayfield Heights, OH (US)

(72) Inventor: Larry T. SMITH, Mayfield Heights, OH (US)

(73) Assignee: MATERION CORPORATION, Mayfield Heights, OH (US)

(21) Appl. No.: 19/167,122

(22) PCT Filed: Mar. 22, 2024
(86) PCT No.: PCT/US2024/021039

§ 371 Date: Sep. 19, 2025

Related U.S. Application Data
(60) Provisional application No. 63/491,584, filed on Mar. 22, 2023.

(51) Int. Cl. H05B 3/14; H05B 3/28; H10P 72/00

(52) U.S. Cl. CPC H05B 3/143; H05B 3/283; H10P 72/0432; H05B 2203/016; H05B 2203/017

(57) ABSTRACT

Disclosed is a process of forming a pedestal with an integral resistance heater. The process may comprise applying a metal layer in a pattern on a beryllium oxide ceramic body, wherein the pattern of the metal layer is connected to a conductor, contacting a first surface of a substrate with the metal layer to position the substrate in line with the ceramic body to form a pre-assembly body, wherein the substrate comprises a ceramic, and heating the pre-assembly body to a joining temperature from 800° C. to 1900° C. to form a heating element that joins the substrate to the ceramic body, wherein the pattern retains integrity when forming the heating element. The metal layer may comprises from 10% to 100% by weight of niobium.

### PRIORITY CLAIM

The present application claims priority to U.S. Provisional Application No. 63/491,584, filed on Mar. 22, 2023, the entire contents and disclosure of which is hereby incorporated by reference.

### FIELD

The present disclosure relates to a pedestal for semiconductor processing and in particular a pedestal that can be used to heat a wafer. In one embodiment, there is provided a process for making an integral resistance heater that uses a niobium containing metal layer functioning as the heater and is able to join the ceramic bodies.

### BACKGROUND

In many high temperature wafer or thin film processing applications, the wafer is treated, e.g., etched, coated, cleaned, and/or has its surface energy activated in a high temperature processing chamber. To perform the treatment, reactive process gases are introduced into the process chambers and then energized to achieve a plasma state. The energizing may be done by applying an RF voltage to an electrode, e.g., a cathode, and electrically grounding an anode to form a capacitive field in the process chamber. The wafer is then treated by the plasma generated within the process chamber to etch or deposit material thereon.

During this treatment process, the wafer may be supported by a pedestal in the process chamber. Ceramic pedestals have several advantages including suitability for high temperature processing and sufficient corrosion resistance. However, ceramic pedestals—due to thermal matching considerations to reduce stresses—are limited to certain types of materials. Problems associated with ceramic heaters include that any metal layers or patterns joined or embedded into the ceramic are likely to fail due to the generation of cracks at the interface or within the ceramic bodies, including micro-fractures, or delamination at higher temperatures.

In addition to mechanical stress on the pedestal, several treatment processes benefit from consistent temperature control and in particular temperature uniformity across the pedestal surface that supports the wafer. Various attempts to provide consistent temperature control suffer from complex heating configuration and increased control mechanisms. This further adds costs without adequately providing a desired temperature control.

US Pub. No. 2022/0289631A1 describes a base plate having a top and a bottom and comprising a beryllium oxide composition, containing at least 95 wt % beryllium oxide and optionally fluorine/fluorine ion. The base plate may further comprise a heating element optionally comprising niobium and/or platinum, optionally a coiled and/or crimped heating element and/or an antenna.

US Pub. No. 2017/0295612A1 discloses an integral resistance heater. The heater includes a beryllium oxide (BeO) ceramic body having a first surface and a second surface. A heating element is formed from a metal foil or metallizing paint and is printed onto the top or second surface of the beryllium oxide ceramic body. The heating element may be formed from a refractory metallizing layer, such as molybdenum or tungsten, and bonded to either the first surface or the second surface of the beryllium oxide ceramic body.

Even in view of the existing pedestal technology, the need exists for an improved pedestal having an integral resistance heater that has improved performance, e.g., reduced decomposition, reduced thermal stress, micro-fracture reduction, and/or mechanical degradation, improved temperature uniformity, and/or superior clamping pressure, especially at higher operating temperatures, e.g., above 650° C., while demonstrating no intralayer, inter-layer, or interfacial delamination.

### SUMMARY

The present disclosure relates to electrical resistance heaters integrated onto or within a ceramic body comprising beryllium oxide (BeO) and processes for making the same. The integral resistance heaters find particular application in the field of semiconductor fabrication and manipulation, and will be described with particular reference thereto. However, it is to be appreciated that the present disclosure is also amenable to other like applications.

In one embodiment, the disclosure relates to a process of forming an integral resistance heater comprising applying a metal layer in a pattern on a planar surface of a ceramic body, wherein the pattern of the metal layer is connected to a conductor, wherein the metal layer comprises from 10% to 100% by weight of niobium and wherein the ceramic body comprises beryllium oxide; contacting a first surface of a substrate with the metal layer to position the substrate in line with the ceramic body to form a pre-assembly body, wherein the substrate comprises a ceramic; and heating the pre-assembly body to a joining temperature from 800° C. to 1900° C. to form a heating element that joins the substrate to the ceramic body, wherein the pattern retains integrity when forming the heating element.

In one embodiment, the disclosure relates to a process of forming an integral resistance heater comprising applying a metal layer in a pattern on a recessed surface of a ceramic body, wherein the pattern of the metal layer is connected to a conductor, wherein the metal layer comprises from 10% to 100% by weight of niobium and wherein the ceramic body comprises beryllium oxide, contacting a first surface of a substrate with the metal layer to position the substrate in contact with a non-recessed surface of the ceramic body to form a pre-assembly body, wherein the substrate comprises a ceramic, and heating the pre-assembly body to a joining temperature from 800° C. to 1900° C. to form a heating element that joins the substrate to the ceramic body, wherein the pattern retains integrity when forming the heating element.

In one embodiment, the disclosure relates to a process of forming an integral resistance heater comprising: applying a metal layer in a pattern on a surface of a beryllium oxide ceramic body, wherein the pattern of the metal layer is connected to a conductor, wherein the metal layer comprises from 10% to 100% by weight of niobium; contacting a first surface of a substrate with the metal layer to position the substrate in line with the beryllium oxide ceramic body to form a pre-assembly body, wherein the substrate comprises a ceramic; and heating the pre-assembly body to a joining temperature from 800° C. to 1900° C. to form a heating element that joins the substrate to the beryllium oxide ceramic body, wherein the pattern retains integrity when forming the heating element.

The process may further comprise pressing the pre-assembly body during heating or before heating or after heating at a contact pressure from 60 kPa to 215,000 kPa. The surface of the beryllium oxide ceramic body may be planar. Alternatively, the surface of the beryllium oxide ceramic body may be recessed to form a channel that includes the pattern and a void space around the pattern. The channel may further comprise beryllium oxide powder to fill the void space prior to heating the pre-assembly body. Prior to heating the pre-assembly body, the beryllium oxide ceramic body may be a green compact of from 56% to 64% theoretical density or the beryllium oxide ceramic body is sintered to greater than 90% theoretical density. The ceramic of the substrate may be beryllium oxide, or may be aluminum oxide. Prior to heating the pre-assembly body, the substrate may be one of: a beryllium oxide powder, a beryllium oxide green compact of from 56% to 64% theoretical density, and a beryllium oxide sintered body of greater than 90% theoretical density. The surface of the beryllium oxide ceramic body may be a planar surface, where the planar surface is opposite the first surface of the substrate. The metal layer may comprise from 35% to 100% by weight of niobium. The metal layer may further comprise platinum, titanium, tantalum, beryllium, alloys thereof, sublayers thereof, or combinations thereof. Heating the pre-assembly body to the joining temperature may be for a duration from 1 second to 7200 seconds. The pattern may be a coil, spiral, maze, unicursal labyrinth, circle, concentric rings, orthogonal, diagonal, parallel, or perpendicular geometry. An integral resistance heater may be made according to this process.

These and other non-limiting characteristics are more particularly described below.

### BRIEF DESCRIPTION OF THE DRAWINGS

A further understanding of the nature and advantages of the disclosed technology may be realized by reference to the remaining portions of the specification and the drawings.

FIG. 1 illustrates a top view of a pattern on a planar surface of a ceramic body according to embodiments herein.

FIG. 2 illustrates a cross-sectional view of the ceramic body according to FIG. 1.

FIG. 3 illustrates a cross-sectional view of an alternate embodiment having the ceramic body as in FIG. 1 where the pattern is partially recessed into the ceramic body.

FIG. 4 illustrates a cross-sectional view of an alternate embodiment having the ceramic body as in FIG. 1 where the pattern is recessed.

FIG. 5 illustrates a cross-sectional view of an assembly as in FIG. 2 further including a substrate according to embodiments herein.

FIG. 6 illustrates a cross-sectional view of an assembly as in FIG. 3 further including a substrate according to embodiments herein.

FIG. 7 illustrates a cross-sectional view of an assembly as in FIG. 4 further including a substrate according to embodiments herein.

FIG. 8 illustrates a cross-sectional view of an assembly having a metal layer pattern on a substrate surface to mirror the metal layer pattern on the ceramic body surface according to embodiments herein.

FIG. 9 illustrates a cross-sectional view of an assembly as in FIG. 5 upon heating according to embodiments herein.

FIG. 10 illustrates a top view of a heating element within channels disposed on a planar surface of a ceramic body according to embodiments herein.

FIG. 11 illustrates a side, exploded view of an integral resistance heater according to the exemplary process.

FIG. 12 illustrates a perspective view of the integral resistance heater as in FIG. 11.

### DETAILED DESCRIPTION

### Introduction

In one embodiment, there is provided a pedestal including a heating element positioned between two ceramic bodies. The heating element may be an integral resistance heater. The ceramic bodies may be bonded together.

Problems previously arose from the integral resistance heaters contributing to mechanically cracking. This was due to thermal expansion mismatch and/or thermal stresses between the ceramics and metal components, e.g., a metal heating element. Specifically, multiple layers of ceramics, including a beryllium oxide (BeO) ceramic body, laminated together previously (e.g., using thin film vapor, a metal foil, a coiled wire, a thick film, or plating) deposited metal (e.g., nickel, molybdenum, or other metal having thermal expansion mismatch) onto the surface of BeO and diffusion bonded produced an inoperable cracked laminate due to thermal stresses.

Accordingly the embodiments disclosed herein meet the demands of integral resistance heaters. The inventors have now developed a process for forming integral resistance heaters by applying a niobium-containing metal layer to join multiple ceramic components. In one embodiment, the process comprises applying a niobium-containing metal layer to join a BeO ceramic body. This process produces an integral resistance heater that is resistant to cracks or fractures, even at higher temperatures. The niobium-containing metal layer may function as both the heater element and functions to join the ceramic bodies. Thus, no additional joining material or braze is necessary and this improves the efficiency of the process while reducing costs.

Disclosed in various embodiments herein are forming processes for integral resistance heaters where the niobium-containing joining metal layer forms a heating element directly in contact with and bonded to a beryllium oxide (BeO) ceramic body. Beryllium oxide ceramic bodies herein are both electrically insulative and highly thermally conductive.

Without being bound by theory, it is postulated that the disclosed processes include a joining temperature that allows bonding between components of the integral resistance heaters while also forming a heating element of the niobium-containing joining metal layer while maintaining integrity of shape of the heating element. Maintaining the integrity of the shape of the heating element is useful to provide consistent temperature control. The subsequent integral resistance heaters can then operate at high temperatures from 600° C. to 800° C. and greater due to the highly refractory niobium-containing joining metal layer.

### Terms

Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to components of like function.

The singular forms “a,” “an,” and “the” include plural referents unless the context clearly dictates otherwise.

As used in the specification and in the claims, the term “comprising” may include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named ingredients/components/steps and permit the presence of other ingredients/components/steps. However, such description should be construed as also describing compositions, articles, or processes as “consisting of” and “consisting essentially of” the enumerated ingredients/components/steps, which allows the presence of only the named ingredients/components/steps, along with any impurities that might result therefrom, and excludes other ingredients/components/steps.

Numerical values in the specification and claims of this application should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently combinable, for example, the range “from 10% to 100% by weight” is inclusive of the endpoints, 10% to 100% by weight, and all the intermediate values.

The process steps described herein refer to temperatures, and, unless provided for, this refers to the temperature attained by the material that is referenced, rather than the temperature at which the heat source (e.g., furnace, oven) is set. The term “room temperature” refers to a range of from 20° C. to 25° C. (68° F. to 77° F.).

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

### Integral Resistance Heater Forming Process

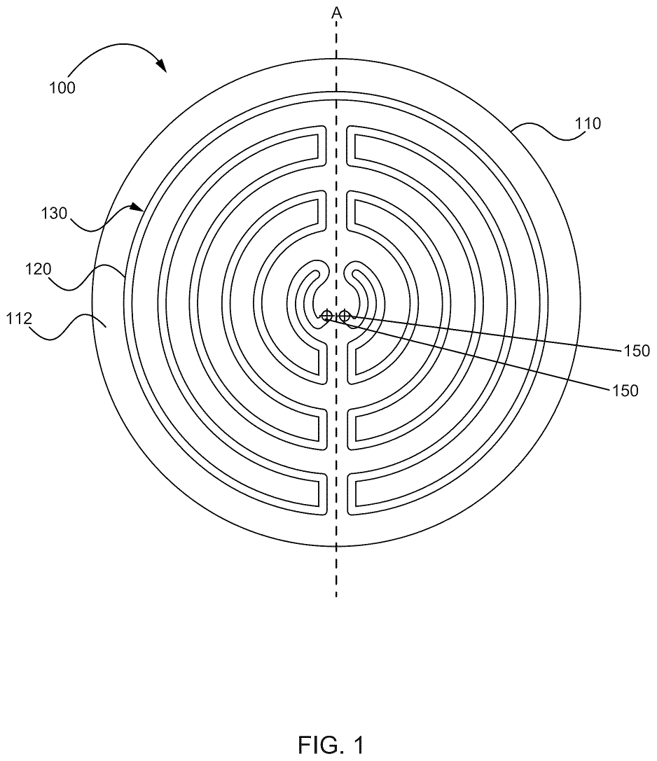

The disclosure relates to a processes for forming integral resistance heaters that have the aforementioned advantages, e.g., free of cracks and having heating element integrity. The process is illustrated in FIGS. 1-12.

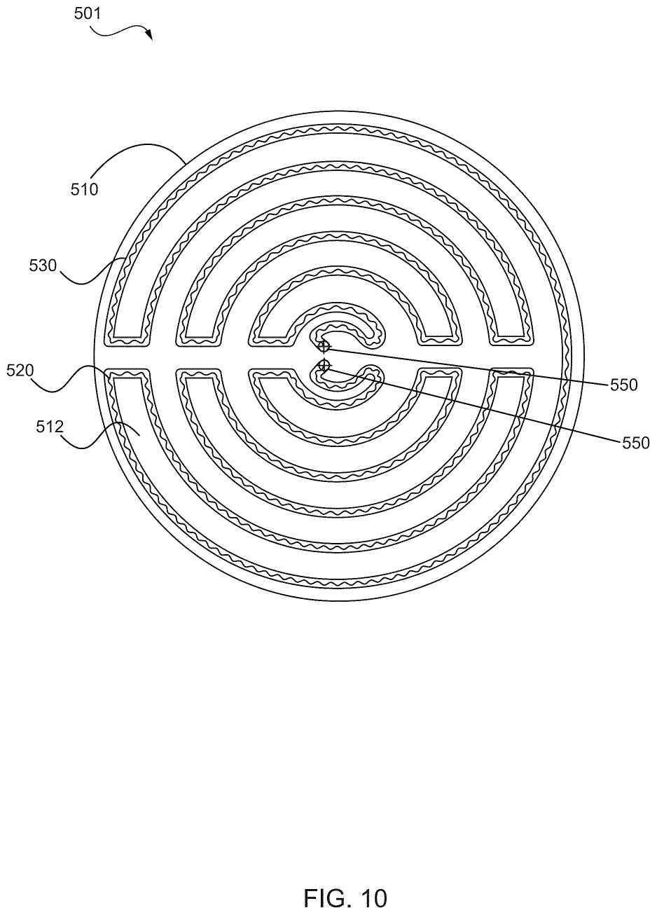

The process comprises the steps of applying a metal layer in a pattern on a surface of a ceramic body (as shown in FIGS. 1-4), contacting a first surface of a substrate with the metal layer (as shown in FIGS. 5-8), and heating to a joining temperature from 800° C. to 1900° C. (as shown in FIG. 9) to form an integral resistance heater having a heating element that joins the substrate to the ceramic body (as shown in FIGS. 10-12).

Importantly, the metal layer comprises from 10% to 100% by weight of niobium and the ceramic body comprises beryllium oxide. Having at least 10% by weight of niobium has been found to provide a heating element that has a closely matched thermal expansion coefficient (CTE) to a beryllium oxide ceramic body. In addition, niobium has a high Thermomechanical Compatibility Factor (TCF), which is an approximate measure of metal suitability for sealing with a ceramic. For example, niobium has a TCF of 88 for alumina seals at 780° C., whereas platinum is 33, copper 20, and titanium, Kovar, nickel, molybdenum, stainless steel, and tungsten each have a TCF of less than 10. Accordingly, thermal stresses may be minimized or eliminated to prevent cracking after forming. In addition niobium has been found to provide a suitable resistive heating that can provide for superior temperature consistency. In one embodiment, the process further includes that the pattern formed of the niobium metal layer retains integrity when forming the heating element. For purposes of the present disclosure, retains integrity refers to a heating element that is not disfigured nor has any discontinuity such as shorting. Because the niobium metal heater may be liquefied to join the ceramic bodies, the liquefaction presents challenges to integrity. To prevent the liquefaction from distorting the integrity, the embodiments disclosed herein operate under certain parameters to retain integrity.

The process may further comprise pressing the pre-assembly body during heating or before heating or after heating at a contact pressure from 60 kPa to 215,000 kPa, e.g., from 75 kPa to 210,000 kPa, from 100 kPa to 150,000 kPa, from 150 kPa to 138,000 kPa or from 150 kPa to 100,000 kPa. Pressing has been found to further join the ceramic bodies with the heating element, and may maintain a desired distance between the substrate and the ceramic body and/or to minimize such distance, i.e., the distance between the ceramic body and the substrate is controllable.

Accordingly, in one embodiment there is provided a process of forming an integral resistance heater comprising applying a metal layer in a pattern on a planar surface of a ceramic body. In one embodiment, the pattern of the metal layer may be connected to a conductor, e.g., a pass through conductor that passes through the ceramic body to control the resistive heating. In one embodiment, another ceramic body or substrate may be positioned in line with the ceramic body and contacts the metal layer to form a pre-assembly body. After assembling the pre-assembly body, the pre-assembly body is heated to a joining temperature from 800° C. to 1900° C. to form a heating element that joins the substrate to the ceramic body. Various embodiments of this processes are described further as follows.

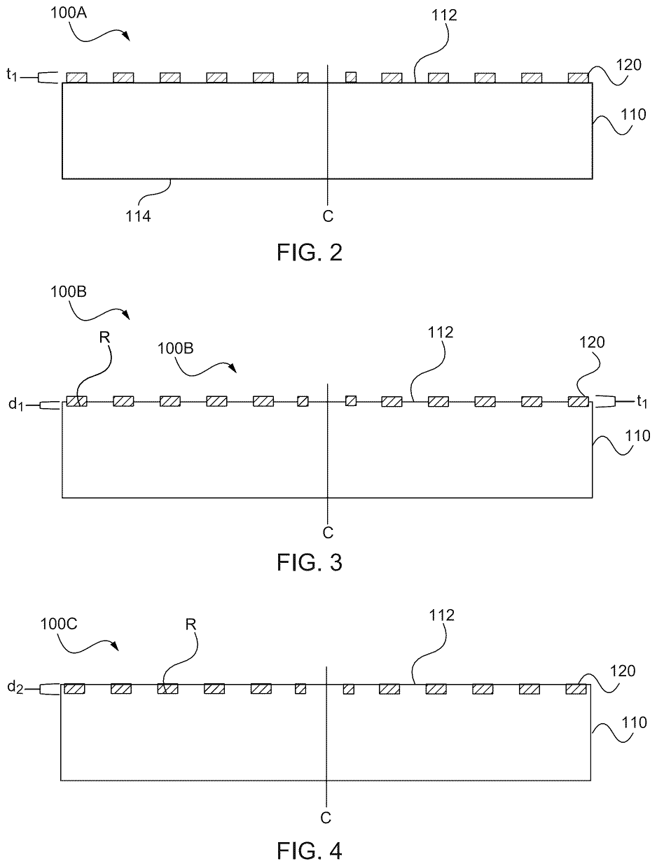

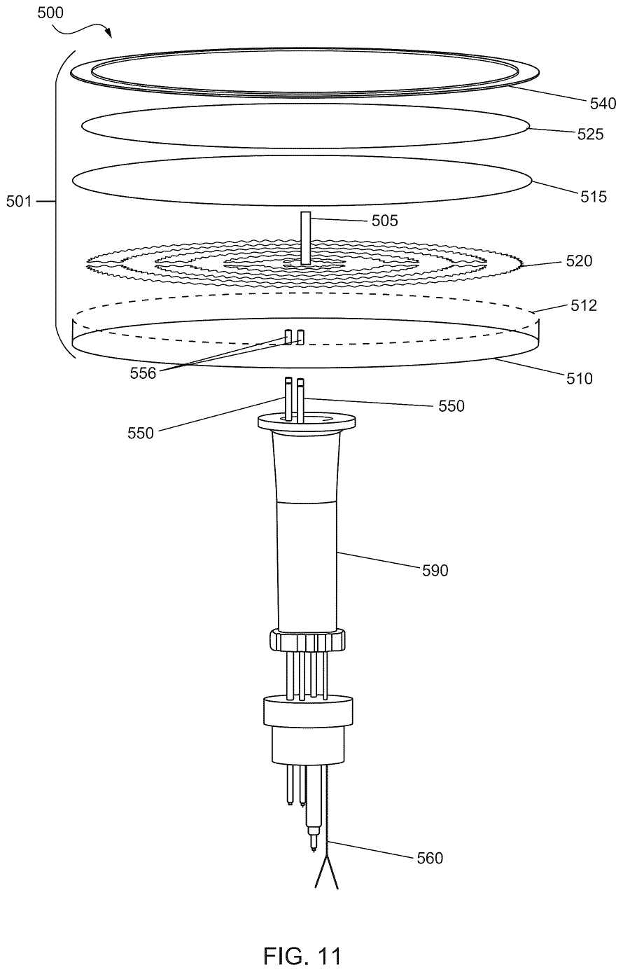

As noted above and as exemplified in FIG. 1, the process includes the step of applying a metal layer 120 in a pattern 130 on a planar surface 112 of a ceramic body 110 to form assembly 100. Conductors (550 as shown in FIG. 11) are connected to ceramic body 110 through holes 150 or (556 as shown in FIG. 11). As shown in FIG. 2, which is a cross-sectional view depicted along line A as in FIG. 1, metal layer 120 may be applied on the planar surface 112 of ceramic body. Ceramic body 110 includes another planar surface 114 that is opposite planar surface 112 of ceramic body 110. Metal layer 120 has a thickness, t, before heating of t₁ in the ceramic body/heating element assembly 100A of FIG. 2. Accordingly, the process may contact a first surface of a substrate with the metal layer to position the substrate in contact with a non-recessed surface of the ceramic body to form a pre-assembly body. In an example, metal layer 120 is a niobium metal foil.

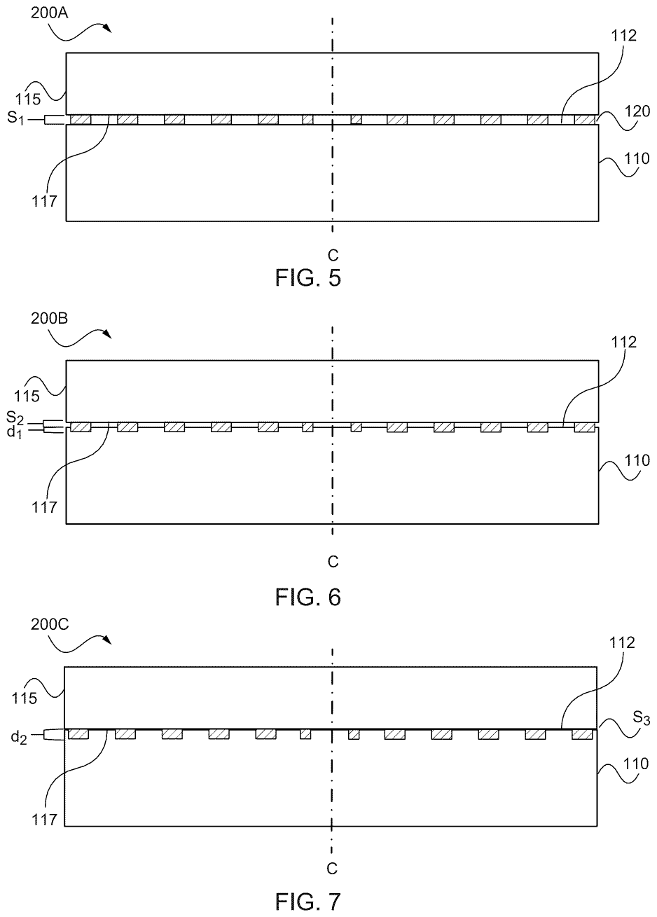

In another embodiment, ceramic body 110 may have recesses, R, for receiving the metal layer 120. Accordingly, the process may contact a first surface of a substrate with the metal layer to position the substrate in contact with a recessed surface of the ceramic body to form a pre-assembly body, such as shown in FIGS. 3 and 4. The recessed portions may be formed when preparing the ceramic body by molds during sintering or post processing machining after forming the ceramic body. The recessed portions may be also referred to as channels herein. Metal layer 120 can be applied to recesses, R, in ceramic body 110 having a recess depth, d_{recess}. The recess depth d₁ illustrated in FIG. 3 and the recess depth d₂ illustrated in FIG. 4 are shown with respect to planar surface 112. In the example as in FIG. 3, the recess depth d₁ is less than the metal layer thickness t₁ so that the metal layer protrudes away from planar surface 112 in the ceramic body/heating element assembly 100B. In some instances (as in FIG. 4) the recess depth d₂ is equal to, or nearly equal to, the metal layer thickness t₁ as in ceramic body/heating element assembly 100C. The recess depth dᵣ may range from 0.1 microns to 1999 microns, e.g., from 0.1 microns to 1500 microns, from 1 microns to 1000 microns, from 1 microns to 500 microns, or from 10 to 250 microns.

In particular embodiments, recesses R create a patterned channel for receiving a niobium or niobium-containing coil therein, where the coil is disposed within the recesses. In some embodiments, the recesses containing the coil may be loaded further with beryllium oxide powder to fill void spaces and/or to cover the coil. In some embodiments, the beryllium oxide powder may cover the coil entirely in order to form a substrate during subsequent heat treatment for co-sintering within the heater assembly.

As mentioned, the process includes applying a metal layer in a pattern on the planar surface, which may be recessed as discussed above, of a ceramic body 110. The metal layer may be applied by physical vapor deposition, chemical vapor deposition, atomic deposition, wet thick film deposit, dry powdered deposit, or combinations thereof. The selection of application method may depend on the shape and size of the BeO ceramic body. The metal layer can form a thick film joins the BeO ceramic body to a substrate and may also form the heating element on the surface of the BeO ceramic body. The desired thickness of the applied metal layer depends on the resistance required to produce heat from current provided by a power supply as well as other factors. The niobium content may also contribute to the electrical resistance. In some embodiments the thickness of the metal layer applied can range from 0.1 microns to 2000 microns, e.g., from 1 micron to 1000 microns, from 1 micron to 100 microns, or from 5 microns to 50 microns, but can be decreased or increased with multiple applications of the metal layer as needed to achieve the desired electrical resistance required to obey Joule's first law of heating.

In one embodiment, the metal layer may be applied as a pre-formed wire, coil (or coiled wire), foil, sheet, plate, mesh, or combinations thereof. The pre-formed metal layer preferably is in the shape of the desired pattern and has a similar thickness as described above.

Suitable patterns of the metal layer onto a planar surface of the ceramic body may vary and are generally useful to provide consistent temperature. In one embodiment, the pattern may provide uniform heating across the surface. In embodiments herein, the pattern may be a coil, spiral, maze, unicursal labyrinth, circle, concentric rings, orthogonal pattern, diagonal pattern, pattern of parallel lines, or pattern of perpendicular geometry. Patterns as described herein are suitable for the BeO ceramic body as heater.

The inherent volume resistivity of niobium contributes, along with diameter and length of the metal layer pattern, to provide a pattern having a cross sectional area adjusted for the ohms law correction required for a joule resistance heating element. Regardless of the pattern, the pattern is connected to conductor(s) for controlling resistive heating. In one embodiment, the pattern of the metal layer is connected to conductors that extend through the ceramic body. The conductor(s) may extend through an opening in the ceramic body (e.g., connected at hole(s) 150 as in FIG. 1). Conductor(s) (e.g., conductors 550 connected at hole(s) 556 as in FIG. 11) may be a lead wire or similar electrical connection.

The metal layer 120 used in the process comprises at least 10% by weight of niobium. While pure niobium is contemplated, the process may also use alloys or mixtures of niobium. Niobium has a coefficient of thermal expansion that is closely matched with the ceramic body, in particular BeO ceramic bodies. The coefficient of thermal expansion (CTE) of niobium is 7.3 μm/(m·K) at room temperature (RT) and the CTE of a beryllium oxide ceramic body, for example, is 7.4 to 9.0 μm/(m·K) at RT. In one embodiment, the process may use beryllium oxide ceramic bodies that have a CTE from 7.4 to 8.0 μm/(m·K) at RT.

The niobium may be of high purity. For example, the niobium may have a purity greater than (and including) 2N (99%), e.g., 3N (99.9%) or 4N (99.99%). In some embodiments, the niobium has a purity of 3N. In some cases, the niobium has a purity greater than (and including) 3N. The purity of niobium is important because the purity effects the inherent volume resistivity. The cross sectional area of the metal layer pattern is adjusted according to the purity to obtain the desired resistance. In some instances, a surface oxide may be desired for adhesion to the ceramic body surface, however, in other instances a surface oxide may not be desired. This is because an oxide layer creates an ionic bond with the metal layer and a covalent bond with beryllium oxide ceramic body.

The metal layer comprises at least 10% by weight (wt %) of niobium, based on the total weight of the metal layer. In some embodiments, the metal layer comprises from 10 wt % to 100 wt % niobium. For example, the metal layer may comprise from 10 wt % to 100 wt % niobium, e.g., from 15 wt % to 100 wt % niobium, 20 wt % to 100 wt % niobium, 25 wt % to 99.99 wt % niobium, 30 wt % to 99.9 wt % niobium, or from 35 wt % to 99 wt % niobium. In terms of lower limits, the metal layer may comprise greater than 10 wt % niobium, e.g., greater than 15 wt % niobium, greater than 20 wt % niobium, greater than 25 wt % niobium, greater than 30 wt % niobium, or greater than 35 wt % niobium. In terms of upper limits, the metal layer may comprise less than 100 wt % niobium, e.g., less than 99.99 wt %, less than 99.9 wt %, less than 99 wt %, less than 95 wt %, less than 90 wt %, less than 85 wt %, less than 80 wt %, less than 75 wt %, less than 70 wt %, or less than 65 wt %. In some embodiments, the metal layer is 100 wt % niobium based upon the total weight of the metal layer before heating.

The metal layer may comprise at most 90% by weight of metals other than niobium in the form of a mixture or alloy. In other words, in addition to the niobium as described above, the metal layer may further comprise platinum, titanium, tantalum, beryllium, alloys thereof, or combinations thereof. These metals may be referred to herein as “metals other than niobium”.

In some embodiments, the metal layer comprises from 0 wt % to 90 wt % metals other than niobium, e.g., platinum, titanium, tantalum, beryllium, alloys thereof, or combinations thereof. For example, the metal layer may comprise from 0 wt % to 90 wt % metals other than niobium, e.g., from 0 wt % to 85 wt % metals other than niobium, from 10 wt % to 75 wt %, or from 25 wt % to 50 wt %. In terms of lower limits, the metal layer may comprise greater than 0 wt % metals other than niobium, e.g., greater than 5 wt %, greater than 10 wt %, greater than 15 wt %, greater than 20 wt %, or greater than 25 wt % metals other than niobium. In terms of upper limits, the metal layer may comprise less than 90 wt % metals other than niobium, e.g., less than 85 wt %, less than 75 wt %, or less than 50 wt %. In some embodiments, metals other than niobium are included in the amount of 35 wt % based upon the total weight of the metal layer before heating.

In some embodiments, the metal layer comprises a niobium alloy comprising 89 wt % niobium, 10 wt % hafnium, and 1 wt % titanium, e.g., the metal layer may comprise a C103 alloy. In other embodiments, the metal layer comprises a niobium alloy according to the standard ASTM-B392, for example Niobium RO4210, which can contain the following elements in addition to Nb: C, N, O, H, Zr, Ta, Fe, S, W, Ni, Mo, Hf, Ti, and Al. Other non-limiting examples of niobium alloys according to the standard include: Niobium R04200, Nb-1% Zirconium R04251, and Nb-1% Zirconium R04261. In addition to niobium, these alloys according to the standard can contain the following elements: C, N, O, H, Zr, Ta, Fe, S, W, Ni, Mo, Hf, Ti, B, Al, Be, and Cr.

In some embodiments, the metal layer further includes a coating layer comprising gold, copper, nickel, silver, palladium, indium, molybdenum, tungsten, titanium, or combinations thereof. The coating layer may be a continuous or non-continuous coating. The coating may be applied to the metal layer (or preform) before positioning/applying the metal layer to the ceramic body.

In other aspects, the metal layer and/or the planar surface of the ceramic body to which the metal layer is disposed may be treated to enhance bonding. The metal layer, e.g., a niobium-containing metal layer, in contact with the planar surface of the ceramic body may be treated to include an oxidation or sub-oxide layer at the metal layer/ceramic body interface. This layer can aid covalent and/or ionic bonding. In another example, a first niobium-containing metal layer may be in contact with a second niobium-containing metal layer to enhance bonding. Treatments to the metal layer may include removing an oxide layer, pretreating to affect surface finish, or coating with another metal such as nickel. In other examples, to prepare the planar surface of a ceramic body for applying the metal layer, the ceramic body may be pre-treated or coated with titanium, titanium oxide, or combinations thereof. In some embodiments, the metal layer further provides bonding or enhanced bonding to a beryllium oxide body, a beryllium oxide substrate, or both, whereby a foil, a printed metal layer, or a coil is pre-treated or coated to provide self-brazing upon heating.

Other bonding techniques may be introduced to bond a beryllium oxide body and a beryllium oxide substrate directly to one another by: (1) using a sealing glass melted between the interfaces between the BeO body and BeO substrate which are then cooled to make a hermetic seal and/or (2) using a eutectic braze melted between the BeO body and BeO substrate and then cooled. The glass or braze used has a melting point that is at least 100° C. higher than the operating temperature of the heater, and is typically in a range of 200° C. to 700° C. higher than the operating temperature of the heater.

The process including applying a metal layer as described above further includes that the ceramic body is a beryllium oxide (BeO) ceramic body. The ceramic body 110 as shown in FIGS. 1-7 is beryllium oxide. The planar surface 112 of the BeO ceramic body as in FIG. 2 is opposite surface 114 of ceramic body 110.

BeO ceramic bodies as used herein may have the following properties (in addition to the CTE mentioned above) that make beryllium oxide ceramic bodies well suited for integral resistance heaters: a high melting point 2514 to 2626° C., a thermal conductivity of from 209 to 330 W/(m·K), a relative dielectric constant of from 6.1 to 7.5 @ 1 MHz, and a bulk resistivity of greater than 1e15 Ω/cm at RT. BeO, depending upon the grade, may alternatively have a lower melting point, e.g., as low as 800° C., or a lower thermal conductivity, e.g., as low as 150 W/(m·K). The beryllium oxide grade affects chemistry/purity, grain structure, and density.

BeO ceramic bodies as used herein may be dense, sintered bodies. The BeO ceramic body preferably has a density greater than 90% of the theoretical density, which is about 3.008 g/cm and a microstructure free of porosity, voids, or other defects. In terms of lower limits the BeO ceramic body can have a density greater than 90%, greater than 91%, greater than 92%, greater than 93%, or greater than 94% of the theoretical density.

BeO ceramic bodies as used herein may alternatively include green compacts that are then further processed to sinter along with one or more other assembly components, e.g., a BeO substrate and/or a metal layer. The BeO green compacts may be formed by cold pressing or cold isostatic pressing or the like to form compacts that have a density lower than the final density of the BeO ceramic body upon sintering to the densities as in the above paragraph. The BeO green compacts preferably has a density greater than 50% of the theoretical density. In terms of lower limits the BeO green compacts can have a density greater than 50%, greater than 53%, or greater than 56% of the theoretical density. In terms of upper limits the BeO green compacts can have a density less than 70%, less than 67%, or less than 64% of the theoretical density. In particular embodiments, the BeO green compacts has a density ranging from 56% to 64% of the theoretical density. Advantageously, the BeO green compacts, which may include a binder, are machinable to effect changes in shape, to flatten, to round, and/or to provides recesses or channels in the BeO body. The BeO green compacts are then further processed to full density to form the integral resistance heater as part of the assembly. Non-limiting example means of further processing herein include hot pressing and hot isostatic pressing to form dense, sintered bodies.

BeO ceramic bodies as used herein are of high purity. In some embodiments, the BeO ceramic body has a purity of greater than 90%, e.g., in terms of lower limits the BeO ceramic body can have a purity greater than 95%, greater than 96%, greater than 97%, greater than 98%, greater than 99%, greater than 99.5%, or greater than 99.9%. In some cases, dopants (or impurities) are added to adjust properties, such as thermal, physical, mechanical, chemical, neutronic, dosimetric, electromagnetic, and/or dielectric properties.

BeO ceramic bodies according to embodiments herein may include dopants. Suitable dopants include aluminum, magnesium, silicon, boron, fluorine, lithium, calcium, titanium, iron, yttrium, zirconium, lanthanum, or combinations thereof. In some embodiments, the BeO ceramic body comprises from 1 ppm to 100,000 ppm dopant(s). For example, the BeO ceramic body may comprise from 1 ppm to 100,000 ppm dopant(s), e.g., from 10 ppm to 10,000 ppm dopant(s), or from 100 ppm to 1000 ppm dopant(s). In terms of lower limits, the BeO ceramic body may comprise greater than 1 ppm dopant(s), e.g., greater than 10 ppm dopant(s), or greater than 100 ppm dopant(s). In terms of upper limits, the BeO ceramic body may comprise less than 100,000 ppm dopant(s), e.g., less than 10,000 ppm dopant(s), or less than 1000 ppm dopant(s).

The ceramic body as described above can be any shape suitable, for example, the BeO ceramic body can be in the shape of a square plate, rectangular plate, platen, or disc. The BeO ceramic body in its largest dimension, l₁, such as diameter for a disc shaped body or length for a square or rectangular plate body, can range in size from 25 mm to 500 mm. In particular embodiments, the diameter or length of the BeO ceramic body can range in size from 25 mm to 300 mm. The BeO ceramic body can have a thickness, w₁, ranging from 1 mm to 400 mm. In particular embodiments, the thickness of the BeO ceramic body can range from 2 mm to 25 mm.

The process herein includes the step of positioning a second ceramic body or substrate in alignment with the ceramic body. In one embodiment, the process comprises contacting a first surface of a substrate with the metal layer to position the substrate in line with the ceramic body to form a pre-assembly body 200A as illustrated in FIG. 5, where the planar surface 112 of ceramic body 110 is opposite the first surface 117 of the substrate 115. Pre-assembly body 200A has spacing S₁ between the ceramic body and the substrate, which may equate to the metal layer thickness t₁ as in FIG. 2.

Ceramic body 110 may be aligned with substrate 115 along a center axis C that is perpendicular to planar surface 112 of ceramic body 110. Alternatively, the body 110 and substrate 115 are aligned via positioning through holes, pins, or other.

Similarly as illustrated in FIGS. 6-7, the planar surface 112 of the ceramic body 110 is opposite the first surface 117 of the substrate 115 for pre-assembly bodies 200B and 200C respectively. However, the spacing S₂ and S₃ between the respective ceramic bodies and substrates may be different than S₁ due to differences in recess depth and/or metal layer thickness.

The maximum spacing between planar surface 112 of ceramic body 110 and first surface 117 of substrate 115 is equivalent to the metal layer thickness t as described above, or up to about 2000 microns as in FIG. 5, for which spacing S₁ is equal to t₁. In some instances, the spacing may be less than 0.1 microns, and may have no spacing between the ceramic body and the substrate, such as shown in FIG. 7 where S₃ is zero and surface 112 and surface 117 are in contact with the metal layer and with each other. Embodiments shown in FIGS. 5-7 illustrate the metal layer is applied on a single planar surface of the ceramic body 110, which is then bonded to an opposite planar surface 117 of the substrate, e.g., a beryllium oxide substrate, directly. In other words, the substrate planar surface 117 does not include a metal layer. Other embodiments as described below include where a planar surface of the substrate, e.g., a beryllium oxide substrate, can include a metal layer to mirror the pattern as applied onto the ceramic body planar surface opposite the planar surface of the substrate.

The substrate may be a polycrystalline ceramic, a single crystal ceramic, or combinations thereof. The substrate may be aluminum nitride, aluminum oxide, beryllium oxide, beryllium aluminate, zirconia, lead zirconate titanate (PZT), or combinations thereof. In some embodiments, the substrate is beryllium oxide as is the ceramic body as described above.

Substrates as used herein are also dense, sintered bodies. The substrate preferably has a density greater than 99% of the theoretical density and a microstructure free of porosity, voids, or other defects. In terms of lower limits the substrate can have a density greater than 90%, greater than 92%, greater than 95%, greater than 97%, greater than 98%, greater than 99%, greater than 99.5%, or greater than 99.9% of the theoretical density.

Substrates as used herein may alternatively be formed first as green bodies that are then further processed to co-sinter with one or more other assembly components, e.g., a BeO body and metal layer. The BeO substrate may be formed by cold pressing or cold isostatic pressing or the like to form green compacts that have a density lower than the final density of the BeO substrate upon sintering to the densities as in the above paragraph. The BeO green substrate preferably has a density greater than 50% of the theoretical density. In terms of lower limits the BeO green substrate can have a density greater than 50%, greater than 53%, or greater than 56% of the theoretical density. In terms of upper limits the BeO green substrate can have a density less than 70%, less than 67%, or less than 64% of the theoretical density.

In other embodiments, the substrate may be formed of BeO powder. The BeO powder may be loose (uncompacted), compacted, cold pressed, or cold isostatic pressed. It has been found that the BeO powder may be used to form a substrate upon further processed to full density concurrently with further processing (e.g., hot pressing) with the BeO body and metal layer to form the integral resistance heater. For hot pressing, uniaxial pressing is preferred over isostatic pressing.

The BeO powder may be used to cover a metal layer on a planar surface of the BeO ceramic body. The BeO powder may be used to cover a metal layer on a recessed surface of the BeO ceramic body. The BeO powder may be used to fill any void spaces in the pattern on a recessed surface (channels) of the BeO body (which may be a dense body or a green compact as described above) to which a metal layer or coil has been applied. Advantageously, the BeO powder fill acts as a thermal conductor and this ensures that the niobium metal layer be more fully in contact with the BeO body and/or substrate. By filling the recessed surface with BeO powder, a monolithic heater can be formed upon further processing, e.g., hot pressing, to form a dense integral resistance heater.

Substrates as used herein may be of high purity. In some embodiments, the ceramic substrate has a purity of greater than 90%, e.g., in terms of lower limits the ceramic substrate can have a purity greater than 95%, greater than 96%, greater than 97%, greater than 98%, greater than 99%, greater than 99.5%, or greater than 99.9%.

The substrates as described above be any shape suitable and, for example, similarly shaped as the BeO ceramic body, e.g., the substrate can be in the shape of a square plate, rectangular plate, platen, or disc. The substrate in its largest dimension, l₂, such as diameter for a disc shaped body or length for a square or rectangular plate body, can range in size from about from 25 mm to 500 mm. In particular embodiments, the diameter or length of the substrate can range in size from 25 mm to 300 mm. The substrate can have a thickness, w₂, of from 1 mm to 400 mm. In particular embodiments, the thickness of the substrate can range from 2 mm to 25 mm.

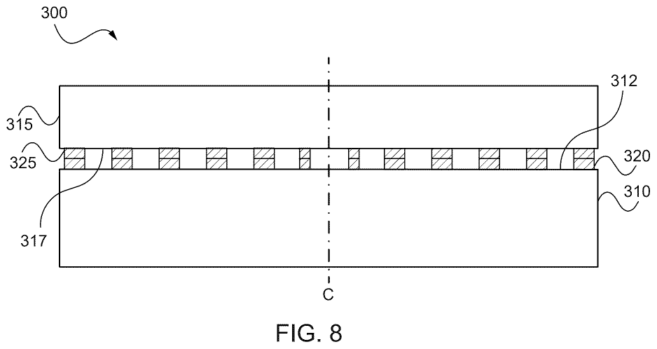

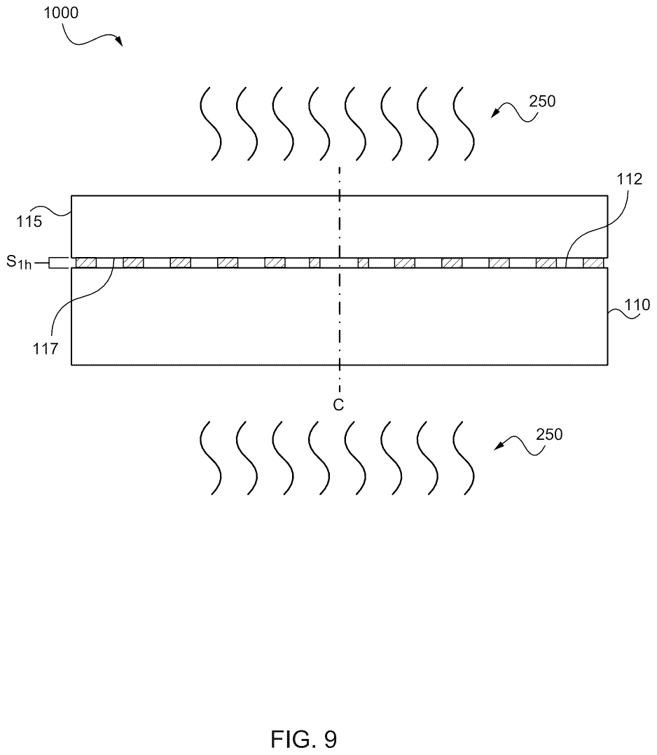

In some other embodiments, the process further includes applying another metal layer as described above onto the surface of the substrate prior to aligning the substrate with the BeO ceramic body. Thus, patterns are applied on both the ceramic body and substrate on surfaces facing one another and the patterns mirroring one another. As illustrated in the cross-sectional view of FIG. 8 of pre-assembly 300, metal layer pattern 325 may be applied onto surface 317 of substrate 315 by similar processes as described above and in the same pattern to mirror the pattern of metal layer 320 applied to the planar surface 312 of ceramic body 310. For example, pre-assembly body 300 includes beryllium oxide ceramic body 310 having metal layer 320 mirroring metal layer 325 as applied to surface 317 of substrate 315. After joining the metal layers 320 and 325, the outer surface of substrate 315, which is opposite surface 317, may further include any of the following (not shown): a bias RF electrode, a wafer contact plate, and a wafer.

As above, the metal layer may be applied by physical vapor deposition, chemical vapor deposition, atomic deposition, wet thick film deposit, dry powdered deposit, or combinations thereof.

According to the processes herein, the pre-assembly bodies (as in FIGS. 5-8) are then heated.

The process further comprises the step of heating the pre-assembly body to a joining temperature from 800° C. to 1900° C. to form a heating element that joins the substrate to the ceramic body. The temperature for heating may be interdependent with the niobium containing metal layer content in terms of whether the metal layer is pure niobium or an alloy thereof. The joining temperature for heating in the processes herein can range from 800° C. to 1900° C., e.g., from 800° C. to 1600° C., from 900° C. to 1200° C., from 900° C. to 1100° C., from 950° C. to 1050° C., or from 975° C. to 1025° C. Operating below 1900° C. prevents the pattern of the metal layer from losing its integrity. Operating above 800° C. is useful to join the ceramic body and substrate. In some embodiments, the joining temperature is about 1000° C.

The joining temperature may vary, i.e., be lower, where, in addition to applying heat, pressure is also applied via hot pressing. In particular embodiments, hot pressing is preferable to provide good bonding of the metal layer to the ceramic body and to the substrate. In embodiments where the BeO ceramic body and/or the BeO substrate is in the green state prior to joining, e.g., when employing BeO loose powder as described herein, hot pressing is preferred.

The joining temperature may also be dependent upon the grade of BeO. Certain grades of BeO may provide for lower bonding temperatures to work with more economical low temperature hot press equipment. However, higher joining temperatures, e.g., at least 950° C. are preferred for improved physical, thermal, and mechanical properties leading to longer heater life.

In embodiments herein, the heating is performed in a non-oxidizing environment. Non-oxidizing environments may include in a vacuum, or in a non-oxidizing gas such as nitrogen or argon, or in a reducing gas such as hydrogen. A non-oxidizing environment assists in retaining the integrity of the pattern.

In embodiments herein, the heating is performed for a duration from 1 second to 7200 seconds, or 120 minutes. The time may be interdependent with the temperature for heating. In some embodiments, the heating is performed for a duration of 1 second to 120 minutes, from 1 minute to 90 minutes, or from 30 minutes to 60 minutes.

As discussed above, the joining temperature may be from 10° C. to 50° C. below the melting temperature of the metal layer. In some examples, the joining temperature may be from 800° C. to 1900° C., e.g., from 900° C. to 1800° C., from 950° C. to 1500° C. or from 1000° C. to 1200° C. Depending upon the metal layer composition, the joining temperature may be greater than, equal to, or less than the liquidus temperature. The liquidus temperature for a pure metal may be equal to its melting temperature. For a metal layer consisting essentially of 100% niobium, the liquidus temperature is 2477° C. For example, in embodiments wherein the metal layer is 100% niobium, the joining temperature is less than the liquidus temperature. In some embodiments, the joining temperature is less than or equal to the liquidus temperature of the metal layer. In particular examples, the joining temperature may be 950° C. or 1000° C.

In other embodiments, where the metal layer comprises niobium and a metal other than niobium as described above, the joining temperature is greater than or equal to the eutectic temperature of the metal layer or the joining temperature is less than or equal to the eutectic temperature of the metal layer. For a metal layer including niobium and another metal other than niobium (as described above) the eutectic temperature may be less than at least one of the liquidus temperature of pure niobium and/or the liquidus temperature of the metal other than niobium.

Importantly, the pattern of the heating element formed retains its integrity when forming the heating element. In other words, after heating the thickness of the metal layer as well as the spacing between the ceramic body and the substrate is maintained. Heating 250 of assembly 1000 is shown as in FIG. 9 (referring back to the pre-assembly body as shown in FIG. 5) and this heating may affect the spacing (S₁ as in FIG. 5) so that the spacing is S₁ₕ after heating. The change in spacing may be ΔS, or [(S₁−S₁ₕ)/S₁]*100%, and is minimal and does not create pathways that can lead to shorting. The ΔS for the integral resistance heaters herein can be less than 10%, less than 5%, less than 4%, less than 3%, less than 2%, or less than 1%. In this way, the integrity of the metal layer is maintained.

Without being bound by theory, the process herein includes providing a temperature so that the metal layer is semi-fluid, e.g., at or just below the liquidus or eutectic temperature for a brief time so as to limit the time that the metal layer is completely fluid.

An average spacing between the substrate and ceramic body after heating is from 0.1 microns to 2000 microns, e.g., from 1 microns to 1000 microns, from 1 microns to 750 microns, 5 microns to 500 microns or from 10 microns to 200 microns.

The integrity of the metal layer being maintained can also be viewed in terms of not changing shape of the pattern appreciably. In some embodiments, a contact angle between the metal layer and the substrate is less than the minimum thickness of the layer. The contact angle between the metal layer and the substrate is ideally static in a range from 90 to 101 degrees to maintain metal layer integrity.

The process may optionally comprise cold pressing or cold isostatic pressing to form a green compact for the BeO ceramic body or for the substrate or both. This includes preparing loose BeO powder with an optional binder in a mold, sealing for water tightness, and subjecting the mold containing the BeO powder to isostatic pressure at room temperature to prove a green compact that is machinable. The contact pressure may range from 6900 kPa to 276,000 kPa. In some embodiments, the contact pressure is 138,000 kPa (138 MPa).

The process may optionally comprise sintering of the BeO ceramic body or substrate, separately, or both. Sintering to form a dense BeO ceramic body and/or substrate can be performed in a refractory lined kiln at temperatures ranging from about 1400° C. to 1900° C., or from 1500° C. to 1600° C., or at about 1550° C. This process of sintering in a kiln is performed without pressure and may be in an oxidizing environment.

In one embodiment, the process may optionally comprise the step of pressing the pre-assembly body, e.g., via hot pressing. Pressure can be applied during heating or before heating or after heating at a contact pressure. The pressure applied assists with the bonding integrity of the resultant heating element to one or both of the ceramic body and the substrate. The contact pressure may range from 60 kPa to 215,000 kPa. In some embodiments, the contact pressure is about 1000 psi (6895 kPa). The heating may be performed in a non-oxidizing environment or in a vacuum. In an example embodiment, the heating is performed at a temperature of 1000° C. at a contact pressure of 1000 psi for a time of 30 minutes under vacuum, e.g., less than 500 mtorr, partial pressure of argon. Non-limiting example means of pressing herein include hot pressing and hot isostatic pressing.

The pressure should not be so great as to deform the metal layer and/or to decrease the spacing between the ceramic body and the substrate more than desired.

Hot pressing can be performed after any of the aforementioned steps to form the assembly. In certain embodiments, a BeO ceramic body is first formed by cold pressing alone or in combination with sintering and then subsequently hot pressed as a component in an assembly. Further, a substrate may be formed by loose BeO powder alone or in combination with cold pressing and/or by sintering and then subsequently hot pressed as a component in an assembly. In particular embodiments, the assembly may be hot pressed uniaxially between graphite punches at 5302 kpa of pressure for 1 hour at 950° C. to form a dense BeO integral resistance heater.

### Integral Resistance Heater

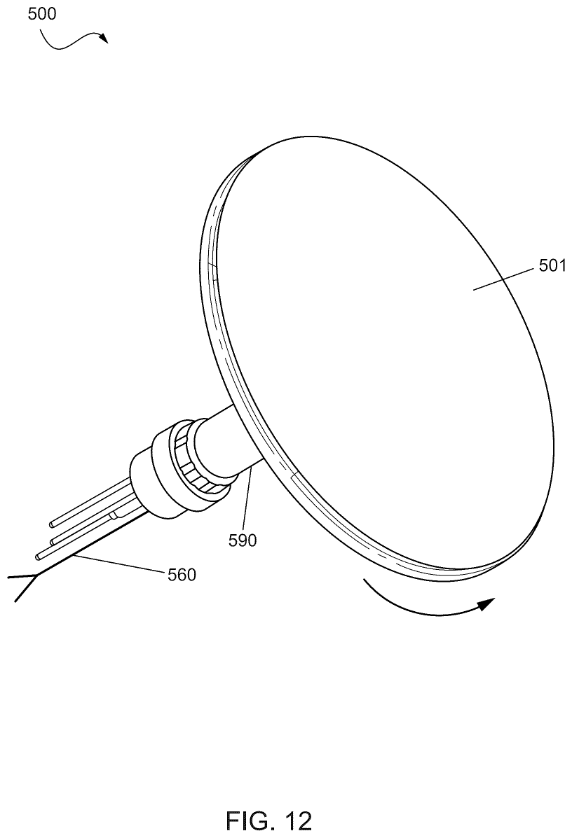

As exemplified in a top plan view of assembly 501 (a view from above metal layer 520) as in FIG. 10 is a partial view of the integral resistance heater 500 as shown in FIGS. 11 and 12. The processes herein may include the step of inserting a niobium (or niobium-containing) metal coil 520 in a pattern of channels 530 disposed recessed from planar surface 512 of a ceramic body 510 to form assembly 500. Conductors (550 as shown in FIG. 11) are connected to ceramic body 510 through holes 556. Metal coil 520 may alternatively be a foil or metal layer 120 (as shown in FIG. 1) applied onto a planar surface of the ceramic body (or onto recessed surface 530 that forms channels as in FIG. 10). Channels 530 may be filled with loose BeO powder prior to joining the coil to the BeO ceramic body 510 (and substrate 515 as in FIG. 11) via hot pressing to form a monolithic assembly 500.

FIG. 11 illustrates a side, exploded view of an integral resistance heater 500 according to the processes described herein having assembly 501 and metal coil 520 (as shown in FIG. 10). Ceramic body 510 receives conductors 550 from within pedestal shaft 590. Ceramic body 510 may include holes 556 for receiving conductors 550 and for assembly alignment through the various components of assembly 501 including niobium-containing metal coil 520 on top surface 512. Conductors 550 may also be referred to as conductive rods or terminals. Also shown is substrate 515 and RF electrode 525. Connector 505 passes through the pedestal shaft, which is a conduit for all electrical connections in/out of integral resistance heater 500. Connector 505 is a conductor that is attached to RF electrode 525 to provide the ground plane electrical contact in order to bias the electrostatic clamping force; connector 505 may also be included at or near the center of the aligned assembly and extends through the pedestal 590. Power supply connection conductors 550 are for connecting to a power supply (not shown). Disposed adjacent to substrate 515, optionally with bias RF electrode 525 or other component between, may be a wafer contact support 540 having an outer surface for holding a wafer atop heater 500. Metal coil 520 may be deposited on the underside surface of substrate 515 so that it does not electrically short out on RF electrode 525.

FIG. 12 illustrates a perspective view of an integral resistance heater 500 as in FIGS. 10 and 11. The assembly 501 is rotatable to be positioned prior to operation about pedestal shaft 590 (having a center axis) and is connected via power supply connection to a power supply (not shown). Thermocouple 560 may also be disposed within the pedestal. In one embodiment, at least two conductors (e.g., conductors 550 as in FIGS. 10 and 11) may extend through the BeO ceramic body and connect to the heating element, e.g., coil 520 as in FIGS. 10 and 11. These conductors are joined to the BeO ceramic body with either solder, or braze, or tack weld, mechanical screw threads, or by crimping. At least one power source can be connected to the heater conductor for controlling the heating element according to Ohm's law, and its Volts Alternating Current (VAC) equivalent form P(t)=l(t)V(t).

The process may include forming a pedestal with an integral resistance heater as shown in FIG. 12. The process of forming an integral resistance heater may comprise applying a metal layer in a pattern on a surface of a beryllium oxide ceramic body. The pattern of the metal layer is connected to at least one conductor, and the metal layer may comprise from 10% to 100% by weight of niobium. The metal layer may be a pure niobium metal foil or wire, e.g., 100% niobium.

The process may include where the beryllium oxide ceramic body is a green compact of from 56% to 64% theoretical density. The green compact may be formed by filling an elastomer mold with loose beryllium oxide powder (optionally containing a binder that is subsequently burned off so that no binder is present in the final integral resistance heater. The beryllium oxide powder in the mold is sealed and subjected to isostatic pressure at room temperature, e.g., via cold isostatic pressing. The beryllium oxide green compact may be machined to provide that a surface of the beryllium oxide ceramic body is planar or wherein a surface of the beryllium oxide ceramic body is recessed. The recessed surface forms a channel that includes the pattern and also a void space around the pattern. For a surface of the beryllium oxide ceramic body that is planar, a metal layer that is a foil may be preferred; while for a surface of the beryllium oxide ceramic body that is recessed, a metal layer that is a coil is preferred.

The process may include where the beryllium oxide green compact is fired in a refractory lined kiln (at high temperature, e.g., 1500° C. or 1550° C., without pressure) to sinter and form a beryllium oxide ceramic body of greater than 90% theoretical density (a dense, sintered beryllium oxide ceramic body). The hold time, e.g., dwell time, at 1500° C. to 1550° C. is anywhere between 1 hour to 50 hours. This depends on the required activation energy dependent on material mass, cross sectional area, chemistry, kiln operation, desired material properties (physical properties such as grain size and density, mechanical properties such as strength, thermal properties such as thermal conductivity). Ambient air may be used for firing in a kiln as described above for firing the beryllium oxide green compact alone (or a substrate alone). Moisture (water vapor) may be removed, for example, by passing ambient air through a bed of desiccant media. If, in other embodiments the beryllium oxide green compact is co-fired with a niobium metal layer, then to prevent oxidation, a non-oxidizing environment such as preferably argon. In other embodiments, a hydrogen, nitrogen, or a mixed (hydrogen and nitrogen) process gas atmosphere may be used. The process may, in other embodiments, omit the firing/sintering intermediate step and densify at a subsequent heating step.

The process may include contacting a first surface of a substrate with the metal layer to position the substrate in line with the beryllium oxide ceramic body to form a pre-assembly body, wherein the substrate comprises a ceramic. As with the beryllium oxide ceramic body, which can be further processed as a green compact or a dense, sintered body, the substrate can also be a green compact (e.g., formed by cold isostatic pressing) that is optionally fired to form a dense, sintered substrate). Yet another option is that the substrate is formed of loose powder (e.g., beryllium oxide or aluminum oxide powder) that may be densified at a subsequent heating step. In the instance where the substrate is formed of BeO powder, the first surface of the substrate is considered as the beryllium oxide powder particles in contact with the metal layer and also the beryllium oxide ceramic body. Therefore, the pre-assembly body includes the metal layer and may include that one or the other or both of the beryllium oxide ceramic body and the substrate are either green compact(s) or dense, sintered body or bodies. And further the substrate of the pre-assembly body may alternatively be loose beryllium oxide (or aluminum oxide) powder. In addition, the pre-assembly body may further include loose beryllium oxide (or aluminum oxide) powder between the beryllium oxide ceramic body and the substrate, e.g., at an interface with the metal layer in a pattern and/or within any void space in or around the pattern, e.g., filled into the channel of a recessed surface of the beryllium oxide ceramic body.

The process may then include heating the pre-assembly body to a joining temperature from 800° C. to 1900° C. to form a heating element that joins the substrate to the beryllium oxide ceramic body, wherein the pattern retains integrity when forming the heating element.

The process as described herein provides for an assembly that is free of cracks. This is due to the closely matched coefficients of thermal expansion between the niobium metal layer, the beryllium oxide ceramic body, and the substrate. By matching the physical, thermal, and mechanical properties for the niobium metal layer with both the beryllium oxide ceramic body and the substrate provides for the Integral resistance heaters as processed herein to provide long life at high operating temperatures without failure due to cracks.

In some embodiments, any or some of the steps or components disclosed herein may be considered optional. In some cases, any or some of the aforementioned items in this description may be expressly excluded, e.g., via claim language. For example claim language may be modified to recite that the metal layer does not comprise or excludes a particular metal or alloy.

### Examples

Example 1. A niobium heating element was prepared and tested. A niobium heating element made from a 0.762 mm Nb wire (grade ASTM-B-392 RO4210)×285″ long was wrapped around a 2.3 mm diameter mandrel to produce a coil. The niobium coil was stretched to 3.9 meters. Metal terminals were machined to include a shaped dome (or mushroom cap) top portion with a 0.81 mm hole cross drilled through the minor diameter. Each end of the coiled wire was placed into the through hole of the terminals and crimped for high electrical contact. The niobium coil was placed inside a machined channel of an aluminum oxide ceramic body 380 mm OD×13 mm thick for testing. The channel was filled with a high temperature refractory caulk Resbond™ 907GF. The niobium heating element/aluminum oxide assembly was placed inside a thermally insulated chamber. Thermometry was located at the surface of the heater. Alternating current was supplied to the exposed terminals for a period of time until the heater reached the desired setpoint at a temperature of 300° C.
Example 2. A beryllium oxide ceramic body was prepared and tested. An elastomer mold was filled with 9 kg of loose BeO powder and binder, which was then sealed for water tightness. The mold containing the BeO powder was subjected to 138 MPa of isostatic pressure at room temperature to compact the powder into a solid body. The solid BeO body, which was “green” meaning unsintered, was removed from the mold and machined using polycrystalline diamond (PCD) tooling to provide flat and parallel bottom and top opposite surfaces. Also machined into the top surface was a 6 mm wide recessed channel in a pattern for holding a heating element (after subsequent heat treatment). The BeO machined body was fired inside a refractory lined kiln at 1550° C. The fired part was machine ground to 380 mm OD×10 mm in thickness between the top and bottom opposite surfaces. A coiled Nb wire as in Example 1 was placed inside the channel. The assembly was passively heated to 800° C. in a thermally insulated chamber containing a nitrogen atmosphere.
Example 3. A heater assembly with BeO body and BeO substrate for actively heating/testing with a metal heating element was prepared. To form the beryllium oxide body, an elastomer mold was filled with 1.8 kg of loose BeO powder containing a binder, and then sealed for water tightness. The mold containing the BeO was subjected to 138 MPa of isostatic pressure at room temperature to compact the powder into a solid body. The solid BeO body was removed from the mold, and “green” machined flat and parallel using PCD tooling. As in Example 2, a 6 mm wide channel to hold a heating element was then machined into one face. The solid BeO body was fired inside a refractory lined kiln at 1550° C. to sinter. The fired part was machine ground to 230 mm OD×10 mm thick with an 200 mm recessed pocket to hold a metallic foil heating element with terminals. Another BeO body (e.g., substrate) machined to include pass through holes was fired separately and was bonded inside to a recessed pocket above the foil heating element. The heater assembly was placed inside a thermally insulated chamber.

Thermometry was positioned at the surface of the heater. Alternating current was supplied to the exposed terminals for a period of time until the heater reached the desired setpoint. The assembly was heated to 400° C. in ambient air.
Example 4. A fully hot-pressed BeO heater assembly including a niobium heating element was prepared. A graphite die was filled with 4.5 kg of BeO powder. A niobium coil heating element as in Example 1 with attached terminals was placed on top of the powder bed. An additional 4.5 kg of BeO powder was added to cover the heating element. The powder was compacted between graphite punches at 6894 kPa of pressure for 2 hours at 1000° C. to form a solid and dense BeO heater assembly. The outer diameter and thickness of the assembly was machine ground for roundness and flatness. Ultrasound was used to locate the terminals below the surface and machining was used to expose the niobium for the power connection.
Example 5. A beryllium oxide heater assembly having a BeO ceramic body and BeO substrate and a niobium heating element therebetween was prepared, actively heated, and tested.

The BeO ceramic body was prepared as in Example 2. An elastomer mold was filled with 9 kg of loose BeO powder and binder, which was then sealed for water tightness. The mold containing the BeO powder was subjected to 138 MPa of isostatic pressure at room temperature to compact the powder into a solid body. The solid BeO (green) body was removed from the mold and machined using PCD tooling to provide flat and parallel bottom and top opposite surfaces. Also machined into the top surface was a 6 mm wide recessed channel in a pattern for holding a heating element. The BeO machined body was fired inside a refractory lined kiln at 1550° C. The fired part was machine ground to 380 mm OD×10 mm in thickness between the top and bottom opposite surfaces.

A coiled niobium wire as in Example 1 was placed inside the channel with pass through holes to form a ceramic body/niobium coil heating element assembly. Terminal connections were crimped to each end of a 20 gauge pure niobium wire that was 7.2 m long. The wire was coiled with a 5 mm pitch and 3 mm coil diameter to form a heating element 4 m long. The Nb heating element was placed into the channel of a 381 mm round×28 mm thick BeO plate (disk), with the terminal connections passing through holes to the opposite surface.

The assembly was then placed inside a loose powder bed of BeO with beryllium oxide powder to cover the heating element and to fill the channel and empty space around the niobium coil. A BeO substrate (prepared as in Example 3) was placed on top of the coil and the BeO powder. The assembly including the BeO powder was compacted between graphite punches via hot pressing at 5302 kPa of pressure for 1 hour at 950° C. to form a solid and dense BeO heater assembly. The outer diameter and thickness of the heater was machine ground using PCD tooling to provide flat and parallel bottom and top opposite surfaces and also for rounding the sides of the heater connecting the opposite bottom and top opposite surfaces (bottom surface of the BeO ceramic body and top surface of the BeO substrate).

Ultrasound was used to locate the terminals below the substrate top surface and machining was used to expose the niobium for the power connection. The BeO heater was placed inside a thermally insulated chamber. Thermometry was located at the top substrate surface. Alternating current was supplied to the exposed terminals for a period of time until the heater reached the desired setpoint.

The heater reached the target temperature of 800° C. in 350 minutes and was held for 21 minutes at 164 VAC and 26 amps. Test data for the heater of Example 5 is shown in Table 1 below.

TABLE 1
Example 5 Integral Resistance Heater Data

| | Time | | Exhaust | | | | | | |
|---|---|---|---|---|---|---|---|---|---|
| SP^{c} | (min) | PV^{c} | TC^{c} | TC 1 | TC 2 | % out | amps | ohms | watts |
| 0 | 0 | 17 | | | | 0% | 0 | 3.3 | 0 |
| 25 | 6 | 29 | | 30 | 30 | 1% | 2.8 | 3.8 | 0 |
| 40 | 13 | 40 | | | | 3% | 8.8 | 3.5 | 285 |
| 50 | 18 | 50 | | | | 8% | 9.2 | 3.6 | 280 |
| 60 | 30 | 60 | | | | 7% | 8.9 | 3.6 | 270 |
| 70 | 35 | 70 | | | | 9% | 10.4 | 306 | 380 |
| 80 | 40 | 80 | | | | 12% | 11.6 | 3.7 | 480 |
| 90 | 44 | 90 | | | | 12% | 11.5 | 3.8 | 475 |
| 100 | 48 | 100 | | | | 14% | 12.5 | 3.8 | 583 |
| 110 | 52 | 110 | | | | 15% | 13.2 | 3.9 | 660 |
| 120 | 56 | 120 | | | | 16% | 13.9 | 4 | 739 |
| 130 | 60 | 130 | | | | 18% | 14.6 | 4 | 826 |
| 140 | 63 | 140 | | | | 20% | 15.1 | 4.1 | 915 |
| 150 | 67 | 150 | | | | 20% | 15.5 | 4.2 | 980 |
| 160 | 70 | 160 | | | | 21% | 15.8 | 4.3 | 1026 |
| 170 | 74 | 170 | | | | 22% | 16 | 4.3 | 1075 |
| 180 | 78 | 180 | | | | 23% | 16.5 | 4.4 | 1155 |
| 190 | 82 | 190 | | | | 24% | 16.9 | 4.5 | 1240 |
| 200 | 85 | 200 | | | | 25% | 17.4 | 4.5 | 1350 |
| 210 | 88 | 210 | | | | 26% | 17.7 | 4.6 | 1397 |
| 220 | 92 | 220 | | | | 28% | 18.2 | 4.7 | 1520 |
| 230 | 94 | 230 | | | | 28% | 18.4 | 4.7 | 1555 |
| 240 | 97 | 240 | | | | 28% | 18.5 | 4.8 | 1620 |
| 250 | 101 | 250 | | | | 30% | 18.9 | 4.9 | 1680 |
| 260 | 104 | 260 | | | | 30% | 18.9 | 5 | 1740 |
| 270 | 108 | 270 | | | | 30% | 19 | 5 | 1780 |
| 280 | 111 | 280 | | | | 32% | 19.4 | 5.1 | 1860 |
| 290 | 114 | 290 | | | | 32% | 19.6 | 5.1 | 1920 |
| 300 | 118 | 300 | | | | 33% | 19.8 | 5.2 | 2008 |
| 310 | 121 | 310 | | | | 33% | 20 | 5.3 | 2092 |
| 320 | 125 | 320 | | | | 34% | 20.02 | 5.3 | 2120 |
| 330 | 128 | 330 | | | | 35% | 20.05 | 5.3 | 2220 |
| 340 | 132 | 340 | | | | 36% | 20.08 | 5.4 | 2284 |
| 350 | 135 | 350 | | | | 37% | 21.1 | 5.4 | 2374 |
| 360 | 138 | 360 | | | | 38% | 21.4 | 5.5 | 2454 |
| 370 | 142 | 370 | | | | 39% | 21.5 | 5.5 | 2500 |
| 380 | 146 | 380 | | | | 39% | 21.8 | 5.6 | 2615 |
| 390 | 149 | 390 | | | | 40% | 22.1 | 5.6 | 2711 |
| 400 | 153 | 400 | | | | 41% | 22.5 | 5.6 | 2800 |
| 410 | 156 | 410 | | | 523 | 43% | 22.8 | 5.7 | 2886 |
| 420 | 160 | 420 | | | 544 | 43% | 22.8 | 5.7 | 2915 |
| 430 | 164 | 430 | | | 557 | 44% | 23 | 5.7 | 3000 |
| 440 | 167 | 440 | | | 567 | 46% | 23.5 | 5.8 | 3165 |
| 450 | 171 | 450 | | | 581 | 47% | 23.8 | 5.8 | 3250 |
| 460 | 174 | 460 | | | 591 | 47% | 24.2 | 5.8 | 3350 |
| 470 | 177 | 470 | | | 599 | 50% | 24.6 | 5.8 | 3480 |
| 480 | 181 | 480 | | | 613 | 51% | 24.8 | 5.9 | 3575 |
| 490 | 185 | 490 | | | | 52% | 25 | 5.9 | 3660 |
| 500 | 189 | 500 | | | | 53% | 25.5 | 5.9 | 3780 |
| 510 | 192 | | | | | 60% | 27.1 | 5.9 | 4340 |
| Reset | (+73) | | | | | | | | |
| 500 | 265 | 500 | | | | 28% | 18.4 | 5.7 | 2000 |
| 510 | 268 | 510 | | | | 29% | 18.9 | 5.7 | 2037 |
| 520 | 272 | 520 | | 500 | | 32% | 19.5 | 5.7 | 2150 |
| 530 | 276 | 530 | | | | 32% | 19.8 | 5.8 | 2260 |
| 550 | 282 | 550 | | | | 35% | 20.6 | 5.8 | 2416 |
| 560 | 285 | 560 | | | | 37% | 21.1 | 5.8 | 2575 |
| 580 | 290 | 580 | | | 585 | 40% | 22.0 | 5.9 | 2825 |
| 600 | 295 | 600 | | | | 43% | 22.8 | 5.9 | 3023 |
| 620 | 299 | 620 | | | 625 | 44% | 23.1 | 5.9 | 3110 |
| 640 | 304 | 640 | | | | 46% | 23.7 | 6.0 | 3311 |
| 660 | 309 | 660 | | | 661 | 48% | 24.2 | 6.0 | 3480 |
| 680 | 314 | 680 | | | | 51% | 24.8 | 6.0 | 3600 |
| 700 | 319 | 700 | | | 696 | 53% | 25.4 | 6.0 | 3800 |
| 720 | 325 | 720 | | | | 53% | 25.4 | 6.1 | 3945 |
| 740 | 330 | 740 | | | 726 | 55% | 26.1 | 6.1 | 3987 |
| 750 | 334 | 750 | | | | 55% | 25.5 | 6.1 | 4000 |
| 770 | 340 | 770 | | | 748 | 58% | 26.0 | 6.1 | 4200 |
| 790 | 347 | 790 | | | | 59% | 26.0 | 6.2 | 4300 |
| 800 | 350 | 800 | 391 | 729 | 770 | 60% | 27.0 | 6.2 | 4571 |
| 808 | 358 | 808 | 400 | 734 | 776 | 58% | 26.0 | 6.2 | 4260 |
| 808 | 363 | 809 | 403 | 726 | 777 | 55% | 26.0 | 6.3 | 4100 |
| 808 | 368 | 809 | 405 | 725 | 778 | 53% | 25.0 | 6.3 | 4080 |
| 0 | 371 | 808 | | | | 0% | 0.0 | 6.7 | 0 |

The heater as in Example 5 as tested as shown in Table 1 performed well at operating temperatures of 800° C. and without failure. The heater was inspected before and after testing and found to exhibit no cracks formed during heating, holding at temperature, or cooling.
Example 6. A beryllium oxide heater assembly having a BeO ceramic body and BeO substrate and a niobium heating element therebetween was prepared, actively heated, and tested.

The BeO ceramic body was prepared as in Example 2 and Example 5 except that the BeO ceramic body was not fired inside a refractory kiln prior to hot pressing. An elastomer mold was filled with 9 kg of loose BeO powder and binder, which was then sealed for water tightness. The mold containing the BeO powder was subjected to 138 MPa of isostatic pressure at room temperature to compact the powder into a solid body. The solid BeO (green) body was removed from the mold and machined using PCD tooling to provide flat and parallel bottom and top opposite surfaces. Also machined into the top surface was a 6 mm wide recessed channel in a pattern for holding a heating element. The BeO machined body was then loaded with a coiled niobium wire as in Example 1 placed inside the recessed channel to form a green/unfired BeO solid body/niobium coil heating element assembly.

The assembly was then placed inside a loose powder bed of BeO with beryllium oxide powder to cover the niobium coil and to fill the channel and empty space around the niobium coil. BeO powder covering the niobium coil was applied in a thickness so as to form a BeO substrate after hot pressing. The assembly including the BeO powder was compacted between graphite punches via hot pressing at 5302 kPa of pressure for 1 hour at 950° C. to form a solid and dense BeO heater assembly. The outer diameter and thickness of the heater was machine ground using PCD tooling to provide flat and parallel bottom and top opposite surfaces and also for rounding the sides of the heater connecting the opposite bottom and top opposite surfaces (bottom surface of the BeO ceramic body and top surface of the BeO substrate).

Ultrasound was used to locate the terminals below the substrate top surface and machining was used to expose the niobium for the power connection. The BeO heater was placed inside a thermally insulated chamber. Thermometry was located at the top substrate surface. Alternating current was supplied to the exposed terminals for a period of time until the heater reached the desired setpoint.

### Embodiments

The following embodiments are contemplated. All combinations of features and embodiments are contemplated.
Embodiment 1. A process of forming an integral resistance heater comprising: applying a metal layer in a pattern on a planar surface of a ceramic body, wherein the pattern of the metal layer is connected to a conductor, wherein the metal layer comprises from 10% to 100% by weight of niobium and wherein the ceramic body comprises beryllium oxide; contacting a first surface of a substrate with the metal layer to position the substrate in line with the ceramic body to form a pre-assembly body, wherein the substrate comprises a ceramic; and heating the pre-assembly body to a joining temperature from 800° C. to 1900° C. to form a heating element that joins the substrate to the ceramic body, wherein the pattern retains integrity when forming the heating element.
Embodiment 2. The process of embodiment 1, further comprising pressing the pre-assembly body during heating or before heating or after heating at a contact pressure from 60 kPa to 215,000 kPa.
Embodiment 3. The process of either embodiment 1 or embodiment 2, wherein the planar surface of the ceramic body is opposite the first surface of the substrate.
Embodiment 4. The process of any of embodiments 1-3, wherein the metal layer comprises from 35% to 100% by weight of niobium.
Embodiment 5. The process of any of embodiments 1-4, wherein the metal layer further comprises platinum, titanium, tantalum, beryllium, alloys thereof, sublayers thereof, or combinations thereof.
Embodiment 6. The process of any of embodiments 1-5, wherein the ceramic of the substrate is polycrystalline, single crystal, or combinations thereof.
Embodiment 7. The process of any of embodiments 1-6, wherein the ceramic of the substrate is aluminum nitride, aluminum oxide, beryllium oxide, zirconia, lead zirconate titanate (PZT), or combinations thereof.
Embodiment 8. The process of any of embodiments 1-7, wherein heating the pre-assembly body to the joining temperature is for a duration from 1 second to 7200 seconds.
Embodiment 9. The process of any of embodiments 1-8, wherein heating the pre-assembly body to the joining temperature is in a non-oxidizing environment.
Embodiment 10. The process of any of embodiments 1-9, wherein a contact angle between the metal layer and the substrate is from 90 degrees to 101 degrees.
Embodiment 11. The process of any of embodiments 1-10, wherein an average spacing between the substrate and ceramic body is from 0.1 microns to 2000 microns.
Embodiment 12. The process of any of embodiments 1-11, wherein the pattern is a coil, spiral, maze, unicursal labyrinth, circle, concentric rings, orthogonal, diagonal, parallel, or perpendicular geometry.
Embodiment 13. The process of any of embodiments 1-12, wherein the metal layer is applied by physical vapor deposition, chemical vapor deposition, atomic deposition, wet thick film deposit, dry powdered deposit, or combinations thereof.
Embodiment 14. The process of any of embodiments 1-13, wherein the metal layer is a pre-formed wire, foil, sheet, plate, mesh, or combinations thereof.
Embodiment 15. The process of any of embodiments 1-14, wherein the metal layer further includes a coating layer comprising gold, copper, nickel, silver, palladium, indium, molybdenum, tungsten, titanium, or combinations thereof.
Embodiment 16. An integral resistance heater made according to the process of embodiment 1.
Embodiment 17. A process of forming an integral resistance heater comprising: applying a metal layer in a pattern on a recessed surface of a ceramic body, wherein the pattern of the metal layer is connected to a conductor, wherein the metal layer comprises from 10% to 100% by weight of niobium and wherein the ceramic body comprises beryllium oxide; contacting a first surface of a substrate with the metal layer to position the substrate in contact with a non-recessed surface of the ceramic body to form a pre-assembly body, wherein the substrate comprises a ceramic; and heating the pre-assembly body to a joining temperature from 800° C. to 1900° C. to form a heating element that joins the substrate to the ceramic body, wherein the pattern retains integrity when forming the heating element.
Embodiment 18. The process of embodiment 17, further comprising pressing the pre-assembly body during heating or before heating or after heating at a contact pressure from 60 kPa to 215,000 kPa.
Embodiment 19. The process of either embodiment 17 or embodiment 18, wherein the metal layer comprises from 35% to 100% by weight of niobium.
Embodiment 20. The process of any of embodiments 17-19, wherein the metal layer further comprises platinum, titanium, tantalum, beryllium, alloys thereof, sublayers thereof, or combinations thereof.
Embodiment 21. The process of any of embodiments 17-20, wherein the ceramic of the substrate is polycrystalline, single crystal, or combinations thereof.
Embodiment 22. The process of any of embodiments 17-21, wherein the ceramic of the substrate is aluminum nitride, aluminum oxide, beryllium oxide, zirconia, lead zirconate titanate (PZT), or combinations thereof.
Embodiment 23. The process of any of embodiments 17-22, wherein heating the pre-assembly body to the joining temperature is for a duration from 1 second to 7200 seconds.
Embodiment 24. The process of any of embodiments 17-23, wherein heating the pre-assembly body to the joining temperature is in a non-oxidizing environment.
Embodiment 25. The process of any of embodiments 17-24, wherein a contact angle between the metal layer and the substrate is from 90 degrees to 101 degrees.
Embodiment 26. The process of any of embodiments 17-25, wherein the pattern is a coil, spiral, maze, unicursal labyrinth, circle, concentric rings, orthogonal, diagonal, parallel, or perpendicular geometry.
Embodiment 27. The process of any of embodiments 17-26, wherein the metal layer is applied by physical vapor deposition, chemical vapor deposition, atomic deposition, wet thick film deposit, dry powdered deposit, or combinations thereof.
Embodiment 28. The process of any of embodiments 17-27, wherein the metal layer is a pre-formed wire, foil, sheet, plate, mesh, or combinations thereof.
Embodiment 29. The process of any of embodiments 17-28, wherein the metal layer further includes a coating layer comprising gold, copper, nickel, silver, palladium, indium, molybdenum, tungsten, titanium, or combinations thereof.
Embodiment 30. An integral resistance heater made according to the process of embodiment 17.
Embodiment 31. A process of forming an integral resistance heater comprising applying a metal layer in a pattern on a surface of a beryllium oxide ceramic body, wherein the pattern of the metal layer is connected to a conductor, wherein the metal layer comprises from 10% to 100% by weight of niobium; contacting a first surface of a substrate with the metal layer to position the substrate in line with the beryllium oxide ceramic body to form a pre-assembly body, wherein the substrate comprises a ceramic; and heating the pre-assembly body to a joining temperature from 800° C. to 1900° C. to form a heating element that joins the substrate to the beryllium oxide ceramic body, wherein the pattern retains integrity when forming the heating element.
Embodiment 32. The process of embodiment 31, further comprising pressing the pre-assembly body during heating or before heating or after heating at a contact pressure from 60 kPa to 215,000 kPa.
Embodiment 33. The process of any of embodiments 31-32, wherein the surface of the beryllium oxide ceramic body is planar, or wherein the surface of the beryllium oxide ceramic body is recessed.
Embodiment 34. The process of any of embodiments 31-33, wherein the surface of the beryllium oxide ceramic body is recessed to form a channel that includes the pattern and a void space around the pattern.
Embodiment 35. The process of any of embodiments 31-34, wherein the channel further comprises beryllium oxide powder to fill the void space prior to heating the pre-assembly body.
Embodiment 36. The process of any of embodiments 31-35, wherein the beryllium oxide ceramic body prior to heating the pre-assembly body is a green compact of from 56% to 64% theoretical density.
Embodiment 37. The process of any of embodiments 31-36, wherein the beryllium oxide ceramic body prior to heating the pre-assembly body is sintered to greater than 90% theoretical density.
Embodiment 38. The process of any of embodiments 31-37, wherein the ceramic of the substrate is beryllium oxide or aluminum oxide.
Embodiment 39. The process of any of embodiments 31-38, wherein the ceramic of the substrate is beryllium oxide and wherein, prior to heating the pre-assembly body, the substrate is one of: a beryllium oxide powder, a beryllium oxide green compact of from 56% to 64% theoretical density, and a beryllium oxide sintered body of greater than 90% theoretical density.
Embodiment 40. The process of any of embodiments 31-39, wherein the surface of the beryllium oxide ceramic body is a planar surface, and wherein the planar surface is opposite the first surface of the substrate.
Embodiment 41. The process of any of embodiments 31-40, wherein the metal layer comprises from 35% to 100% by weight of niobium.
Embodiment 42. The process of any of embodiments 31-41, wherein the metal layer further comprises platinum, titanium, tantalum, beryllium, alloys thereof, sublayers thereof, or combinations thereof.
Embodiment 43. The process of any of embodiments 31-42, wherein heating the pre-assembly body to the joining temperature is for a duration from 1 second to 7200 seconds.
Embodiment 44. The process of any of embodiments 31-43, wherein the pattern is a coil, spiral, maze, unicursal labyrinth, circle, concentric rings, orthogonal, diagonal, parallel, or perpendicular geometry.
Embodiment 45. An integral resistance heater made according to the process of any of embodiments 31-44.

While the invention has been described in detail, modifications within the spirit and scope of the invention will be readily apparent to those of skill in the art. In view of the foregoing discussion, relevant knowledge in the art and references discussed above in connection with the Background and Detailed Description, the disclosures of which are all incorporated herein by reference. In addition, it should be understood that aspects of the invention and portions of various embodiments and various features recited below and/or in the appended claims may be combined or interchanged either in whole or in part. In the foregoing descriptions of the various embodiments, those embodiments which refer to another embodiment may be appropriately combined with other embodiments as will be appreciated by one of skill in the art. Furthermore, those of ordinary skill in the art will appreciate that the foregoing description is by way of example only, and is not intended to limit.

1. A process of forming an integral resistance heater comprising:
applying a metal layer in a pattern on a surface of a beryllium oxide ceramic body, wherein the pattern of the metal layer is connected to a conductor, wherein the metal layer comprises from 10% to 100% by weight of niobium;
contacting a first surface of a substrate with the metal layer to position the substrate in line with the beryllium oxide ceramic body to form a pre-assembly body, wherein the substrate comprises a ceramic; and
heating the pre-assembly body to a joining temperature from 800° C. to 1900° C. to form a heating element that joins the substrate to the beryllium oxide ceramic body, wherein the pattern retains integrity when forming the heating element.

2. The process of claim 1, further comprising pressing the pre-assembly body during heating or before heating or after heating at a contact pressure from 60 kPa to 215,000 kPa.

3. The process of claim 1, wherein the surface of the beryllium oxide ceramic body is planar, or wherein the surface of the beryllium oxide ceramic body is recessed.

4. The process of claim 3, wherein the surface of the beryllium oxide ceramic body is recessed to form a channel that includes the pattern and a void space around the pattern.

5. The process of claim 4, wherein the channel further comprises beryllium oxide powder to fill the void space prior to heating the pre-assembly body.

6. The process of claim 1, wherein the beryllium oxide ceramic body prior to heating the pre-assembly body is a green compact of from 56% to 64% theoretical density.

7. The process of claim 1, wherein the beryllium oxide ceramic body prior to heating the pre-assembly body is sintered to greater than 90% theoretical density.

8. The process of claim 1, wherein the ceramic of the substrate is beryllium oxide or aluminum oxide.

9. The process of claim 8, wherein the ceramic of the substrate is beryllium oxide and wherein, prior to heating the pre-assembly body, the substrate is one of:
a beryllium oxide powder,
a beryllium oxide green compact of from 56% to 64% theoretical density, and
a beryllium oxide sintered body of greater than 90% theoretical density.

10. The process of claim 3, wherein the surface of the beryllium oxide ceramic body is a planar surface, and wherein the planar surface is opposite the first surface of the substrate.

11. The process of claim 1, wherein the metal layer comprises from 35% to 100% by weight of niobium.

12. The process of claim 1, wherein the metal layer further comprises platinum, titanium, tantalum, beryllium, alloys thereof, sublayers thereof, or combinations thereof.

13. The process of claim 1, wherein heating the pre-assembly body to the joining temperature is for a duration from 1 second to 7200 seconds.

14. The process of claim 1, wherein the pattern is a coil, spiral, maze, unicursal labyrinth, circle, concentric rings, orthogonal, diagonal, parallel, or perpendicular geometry.

15. An integral resistance heater made according to the process of claim 1.
